(19) United States
(12) Patent Application Publication
(10) Pub. No.: US 2007/0148494 A1
(43) Pub. Date: Jun. 28, 2007

(54) Display device

(76) Inventors: Emiko Kambe, Kanagawa (JP); Masayuki Kurotaki, Kanagawa (JP); Tadahiko Yoshinaga, Kanagawa (JP); Yasunori Kijima, Tokyo (JP)

Correspondence Address: ROBERT J. DEPKE;LEWIS T. STEADMAN, ROCKEY, DEPKE, LYONS AND KITZINGER, LLC, SUITE 5450 SEARS TOWER, CHICAGO, IL, 60606-6306, US

(21) Appl. No.: 11/637,539

(22) Filed: Dec. 12, 2006

(30) Foreign Application Priority Data
Dec. 16, 2005 (JP) JP 2005-362655
Oct. 30, 2006 (JP) JP 2006-293641

(51) Int. Cl. H01L 51/54

(52) U.S. Cl. 428/690; 428/917; 313/504; 313/506; 257/E51.05; 257/40

(57) ABSTRACT

A display device including an anode, a cathode, and an organic layer provided with at least a light emitting layer interposed between the anode and the cathode, wherein the organic layer is provided with an electron injection layer which is provided in a state that it comes into contact with the light emitting layer between the cathode and the light emitting layer, and the electron injection layer is configured by using a material having an azaaryl structure.

### CROSS REFERENCES TO RELATED APPLICATIONS

The present invention contains subjects related to Japanese Patent Applications JP 2005-362655 and JP 2006-293641 filed in the Japan Patent Office on Dec. 16, 2005 and Oct. 30, 2006, respectively, the entire contents of which being incorporated herein by reference.

### BACKGROUND OF THE INVENTION

1. Field of the Invention

The invention relates to a display device which is used in color displays and so on and in particular, to a display device of a self-lighting type which is provided with an organic layer.

2. Description of the Related Art

FIG. 5 shows one configuration example of a display device of a self-lighting type which is provided with an organic layer (organic electric field light emitting element). As illustrated in FIG. 5, a display device 1 is configured to have an anode 3 composed of ITO (indium tin oxide; transparent electrode) provided on a transparent substrate 2 made of glass or the like, an organic layer 4 provided on this anode 3 and a cathode 5 further provided on an upper part thereof. The organic layer 4 is configured such that if desired, a light emitting layer 4c is provided via a hole injection layer 4a and a hole transport layer 4b from a side of the anode 3; and that if further desired, an electron transport layer 4d and an electron injection layer 4e are successively stacked. In the thus configured display device 1, light generated when an electron injected from the cathode 5 and a hole injected from the cathode 3 are recoupled with each other in the light emitting layer 4c is extracted from a side of the substrate 2.

In addition to such a configuration, there is a so-called display device of an upward lighting type which is configured by stacking a cathode 5, an organic layer 4 and an anode 3 in this order from a side of the substrate 2 or by further configuring an electrode (upper electrode) positioned in an upper portion thereof by a transparent material, thereby extracting light from an opposite side to the substrate 2. In particular, in an active matrix type display unit having a thin film transistor (hereinafter referred to as “TFT”) on a substrate, a so-called upward lighting element structure in which a display device of an upward lighting type is provided on a substrate having TFT provided thereon is advantageous in view of improving an aperture rate of the light emitting part.

In the upward lighting element structure, though light could be extracted from the both sides by using, as an anode, a transparent electrode made of ITO or the like, in general, an opaque electrode is used, and a cavity structure is used. The thickness of an organic layer of the cavity structure is defined by the light emitting wavelength and can be derived from the calculation of multiple interference. In the upward lighting element structure, by positively employing this cavity structure, the extraction efficiency of light into the outside can be improved, and the light emitting spectrum can be controlled.

In the display device 1 having the foregoing configuration, particularly in the electron transport layer 4d provided between the light emitting layer 4c and the cathode 5, there are generally frequently used alumiquinolinol complexes and derivatives thereof; phenanthroline derivatives (see, for example, Japanese Patent No. 3562652 (Patent Document 1)); and ones having an alkali metal contained in a phenanthroline derivative (see, for example, JP-A-2002-100482 (Patent Document 2)).

As the electron injection layer 4e, there are disclosed a configuration using an organic material having a phthalocyanine skeleton (see, for example, JP-A-2001-43973 (Patent Document 3)) and a configuration using a silole compound (see, for example, JP-A-2000-186094 (claim 5) (Patent Document 4)).

### SUMMARY OF THE INVENTION

Now, in the case of configuring a display unit by using the foregoing display device of a self-lighting type, especially a light emitting element provided with an organic layer, there are important problems such as realization of high efficiency, low-voltage driving, long life and insurance of reliability of the display device. However, in the display devices having the foregoing related-art configuration, the driving voltage is still high, and it could not be said that the light emitting efficiency is sufficient.

Then, it is desired to provide a display device capable of not only devising to lower a driving voltage but also devising to improve a current efficiency and having excellent long-term reliability.

According to an embodiment of the invention, there is provided a display device including an anode, a cathode, and an organic layer provided with at least a light emitting layer interposed between the anode and the cathode. In such a configuration, in particular, the organic layer is provided with an electron injection layer which is provided in a state that it comes into contact with the light emitting layer between the cathode and the light emitting layer, and this electron injection layer is configured by using a material having an azaaryl structure. This electron injection layer is used as a thin film and preferably has a thickness of not more than 10 nm, and more preferably not more than 7 nm.

In a display device having such a configuration, by using a material having an azaaryl structure with very good electron transport properties in the electron injection layer and providing this electron injection layer in a side of the cathode while coming into contact with the light emitting layer, it has become possible to tremendously enhance electron injection properties from the cathode into the light emitting layer and to largely lower a driving voltage.

Also, since the electron injection properties into the light emitting layer are tremendously enhanced, it becomes possible to bias a recoupling region between a hole and an electron in the light emitting layer towards a side of the anode far from the cathode. Thus, extinction due to diffusion of an exciton into the cathode metal is prevented. Moreover, by providing the electron injection layer while coming into contact with the light emitting layer, a structure from which an electron transport layer is omitted therebetween is presented. Accordingly, energy transfer of the exciton in the light emitting layer into the electron transport layer is not generated, and an energy loss of the exciton of the light emitting layer becomes small. Consequently, it is also possible to improve the current efficiency.

In addition, as described previously, since the related-art electron transport layer with a low degree of charge transfer is not provided, a disturbance in charge balance is small, and the stability at the time of driving is kept, thereby achieving a long life. In other words, both an improvement of current efficiency and a long life which have hitherto been considered to be in a reciprocal relationship can be simultaneously achieved, too.

In the light of above, according to the display device according to the embodiment of the invention, it is possible to devise to lower a driving voltage and to improve a current efficiency. Thus, it becomes possible to realize a display unit which is low in electric power consumption and excellent in long-term reliability.

### BRIEF DESCRIPTION OF THE DRAWINGS

FIG. 1 is a sectional view to show a configuration of a display device according to an embodiment of the invention.

FIG. 2 is a graph to show a relationship between an electron injection layer thickness of each of display devices of Examples 1 to 5 and a voltage.

FIG. 3 is a graph to show a relationship between an electron injection layer thickness of each of display devices of Examples 1 to 5 and a current efficiency.

FIG. 4 is a graph to show a relationship between an electron injection layer thickness of each of display devices of Examples 1 to 5 and a life.

FIG. 5 is a sectional view to show a configuration of a display device of an embodiment.

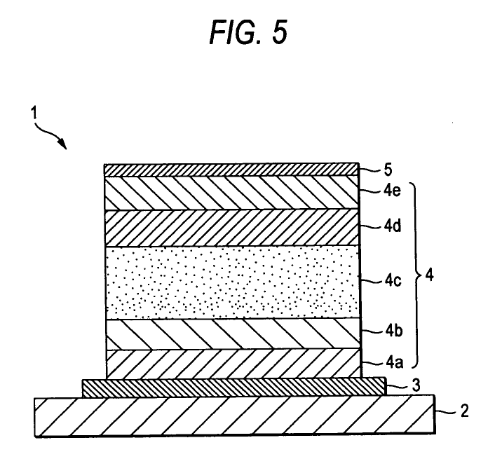

### DETAILED DESCRIPTION OF THE PREFERRED EMBODIMENTS

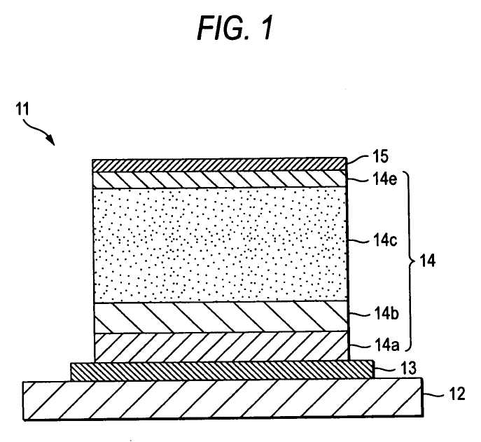

FIG. 1 is a sectional view to show one configuration example of a display device according to an embodiment of the invention. A display device 11 illustrated in FIG. 1 is provided with an anode 13 provided on a substrate 12, an organic layer 14 superposed and provided on this anode 13, and a cathode 15 provided on this organic layer 14.

In the following description, a configuration of a display device of an upward lighting system in which light emitting light generated during coupling of a hole injected from the anode 13 with an electron injected from the cathode 15 within an light emitting layer 14c is extracted from a side of the cathode 15 as an opposite side to the substrate 12 will be described.

First of all, the substrate 12 on which the display device 11 is provided is properly selected and used among transparent substrates such as glass, silicon substrates and film-like flexible substrates. In the case where the driving system of a display unit configured by using this display device 11 is an active matrix system, a TFT substrate having TFT provided therein for every pixel is used as the substrate 12. In this case, the display unit configured by using this display device 11 is of a structure in which the display device 11 of an upward lighting system is driven by using TFT.

As the anode 13 which is provided as a lower electrode on this substrate 12, for the purpose of injecting a hole with good efficiency, materials having a large work function from a vacuum level of an electrode material, for example, chromium (Cr), gold (Au), an alloy of tin oxide (SnO₂) and antimony (Sb), an alloy of zinc oxide (ZnO) and aluminum (Al), an alloy of Ag, and oxides of such a metal or alloy can be used singly in admixture.

In the case where the display device 11 is of an upward lighting system, by configuring the anode 13 by using a high reflective material, an effect for extracting light into the outside can be improved due to an interference effect and a high reflectance effect. For such an electrode material, an electrode containing, as the major component, Al, Ag, etc. is preferably used. By providing a transparent electrode material layer having a large work function such as ITO on such a high reflective material layer, it is also possible to enhance a charge injection efficiency.

Incidentally, in the case where the driving system of the display unit configured by using this display device 11 is an active matrix system, the anode 13 is subjected to patterning for every pixel having TFT provided therein. A non-illustrated dielectric film is provided in an upper layer of the anode 13, and a surface of the anode 13 of each pixel is exposed from an aperture of this dielectric film.

The organic layer 14 is formed by stacking a hole injection layer 14a, a hole transport layer 14b, a light emitting layer 14c and an electron injection layer 14e in this order from the side of the anode 13 and is characterized in that the electron injection layer 14e is provided while coming into contact with the light emitting layer 14c.

As the hole injection layer 14a, usually known hole injecting materials can be used. The hole injection layer 14 may further contain an electron accepting material such as a quinoid skeleton-containing TCNQ based materials, quinone based materials, DCNQI based materials, polycyano based materials, polynitro based materials, and fluorene based materials.

As the hole transport layer 14b, hole transporting materials such as benzidine derivatives, styrylamine derivatives, triphenylmethane derivatives, and hydrazone derivatives can be used.

As the light emitting layer 14c, usually known light emitting materials may be used. However, in particular, in the present configuration, organic materials configured of only carbon and hydrogen may be used, and materials containing a hole transporting tertiary amine in a molecular structure thereof may be used. The material containing a tertiary amine skeleton may be any of a host or a guest. In addition, the light emitting layer 14c may contain a substance capable of emitting phosphorescence.

Such a light emitting layer 14c may be a mixed organic thin film containing, as a dopant, an organic substance such as perylene derivatives, coumarin derivatives, pyran based dyes, and triphenylamine derivatives. In this case, the light emitting layer 14c is formed by dual-source vapor deposition. In particular, if the material containing a hole transporting tertiary amine in a molecular structure thereof has a small intermolecular mutual action and has a characteristic feature that it hardly causes concentration quenching, it can be subjected to high-concentration doping and functions as one of optimum dopants.

In addition, it is preferable that the light emitting layer 14c is made thick such that a total thickness of the light emitting layer 14c and the electron injection layer 14e in view of device design is concretely from approximately 30 to 100 nm.

Next, the electron injection layer 14e which is a characteristic feature of the embodiment of the invention will be described.

As the electron injection layer 14e, in particular, a material configured by using a material having an azaaryl structure or a material having a silole structure, especially a material having an azaaryl structure is suitably used.

Specific examples of the material having an azaaryl structure include materials represented by the following formulae (1) to (25).

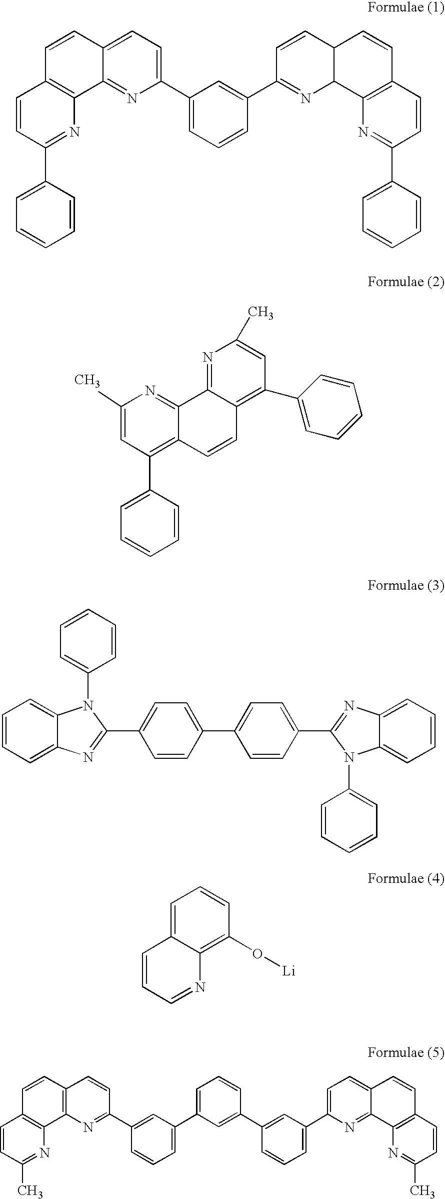

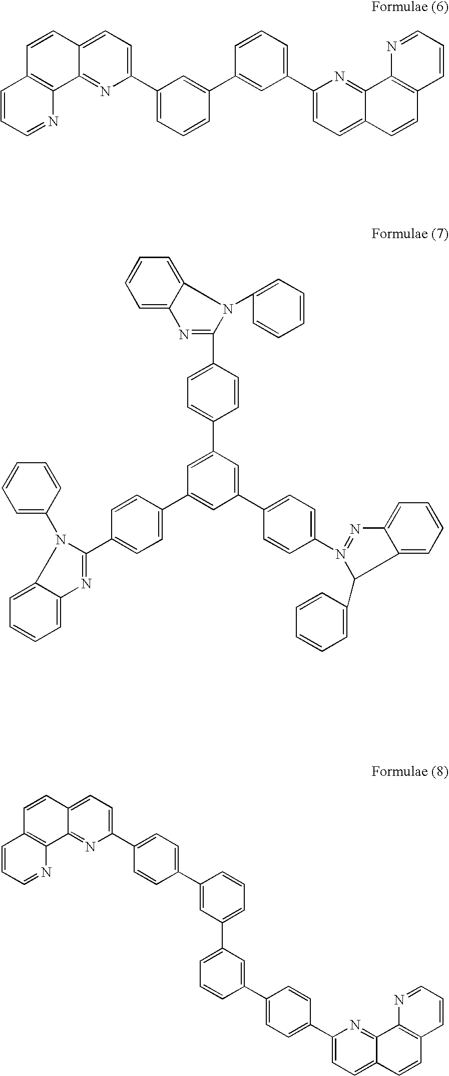

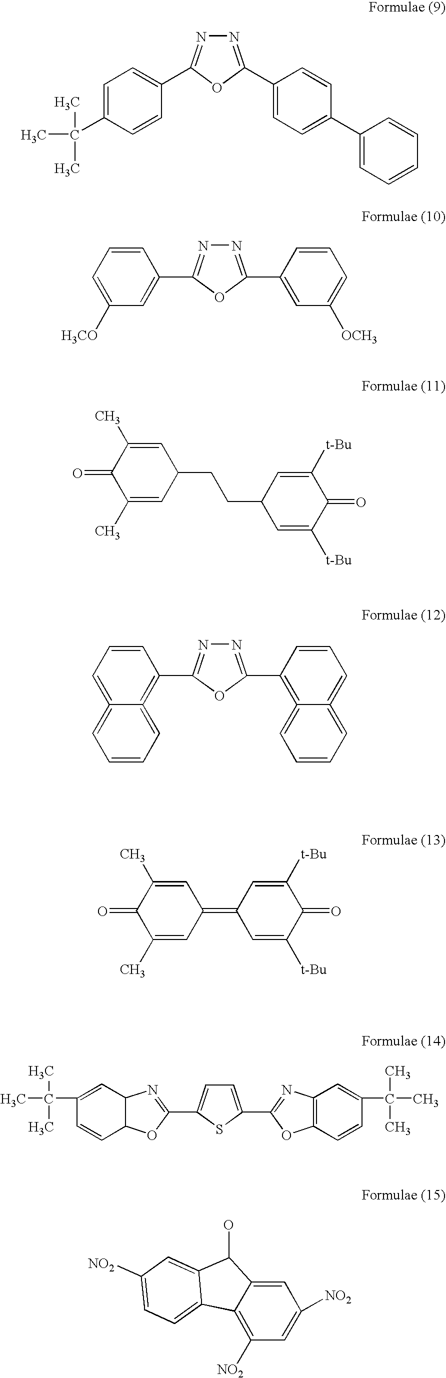

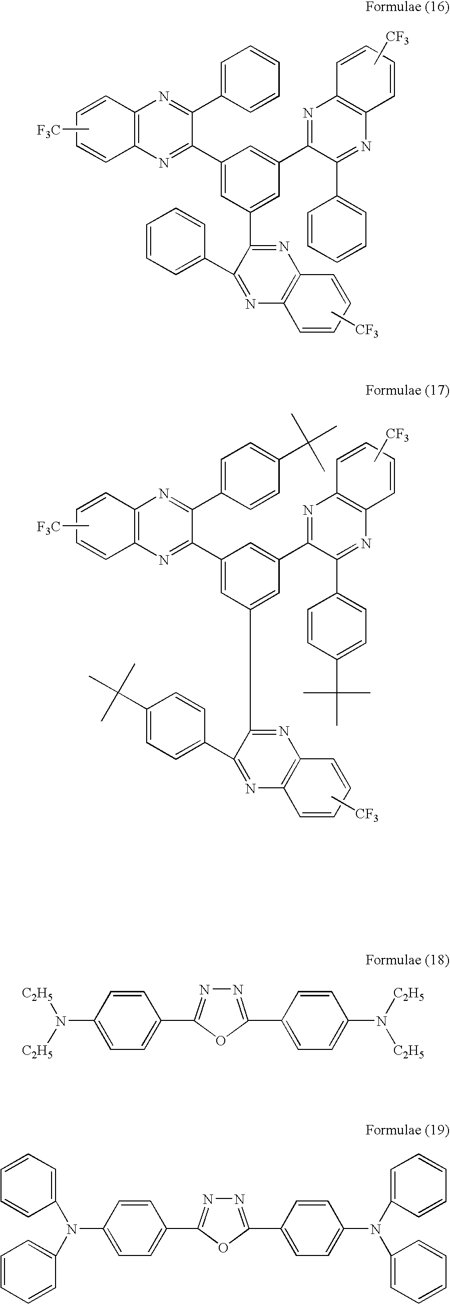

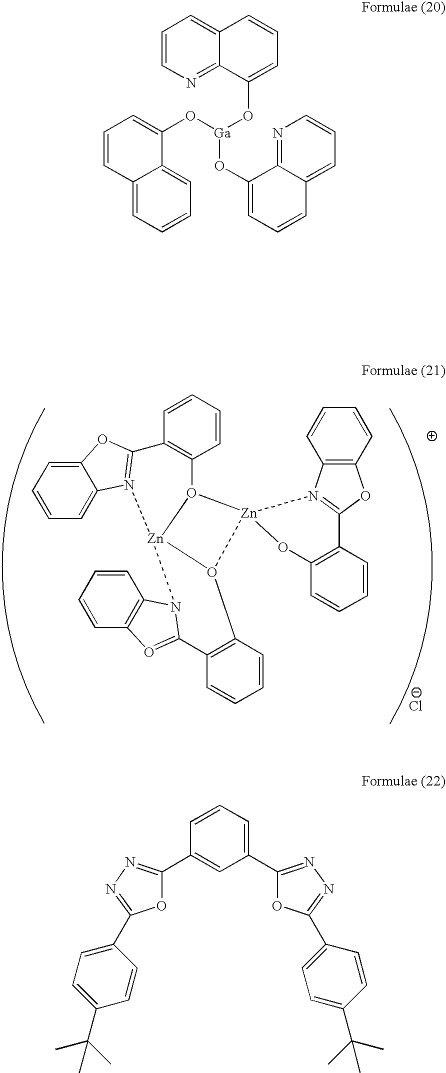

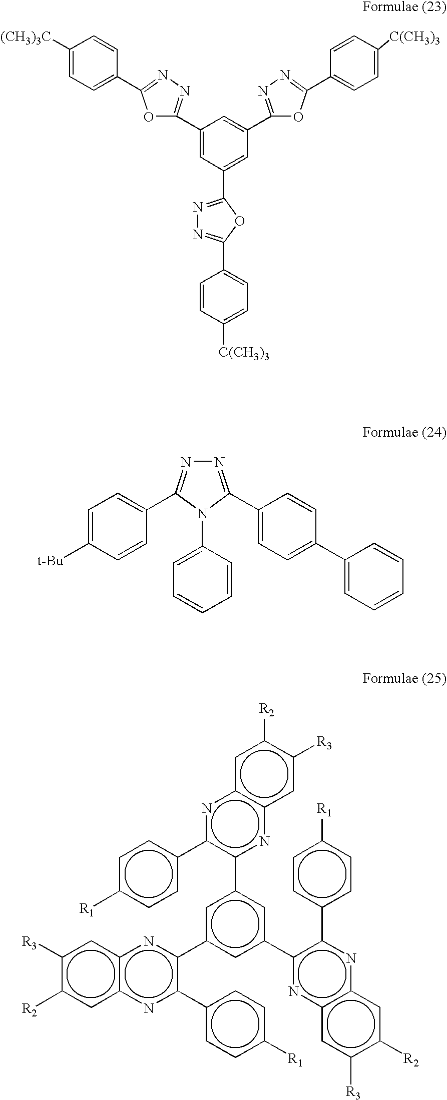

Specific examples of the material having a silole skeleton include materials represented by the following formulae (26) and (27).

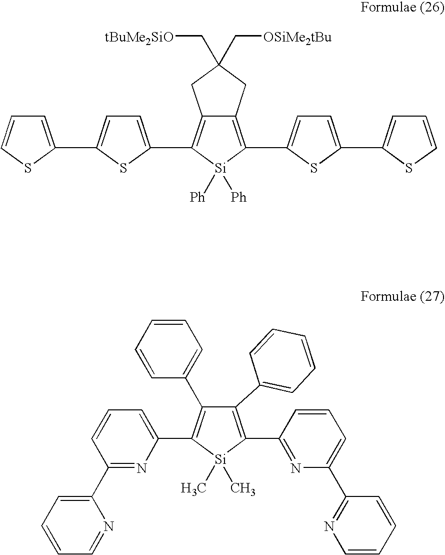

The electron injection layer 14e configured by using such a material may contain at least one of alkali metals, alkaline earth metals, lanthanoids (for example, La, Ce, Pr, Nd, Sm, Eu, Gd, Tb, Dy, Ho, Er, Tm, Yb, and Lu), and oxides, complex oxides and fluorides thereof.

It is preferable that such an electron injection layer 14e is provided in a thickness as thin as possible. The thickness of the electron injection layer 14e is preferably not more than 10 nm, and more preferably not more than 7 nm. However, taking into consideration an actual mass production process, the thickness of the electron injection layer 14e is set up in the range of not more than 10 nm or not more than 7 nm in view of the productivity and thickness control.

Each of the layers 14a to 14e configuring the organic layer 14 is formed by, for example, a vacuum vapor deposition method or other method such as a spin coating method.

It is not precluded that each of these respective layers 14a to 14e is provided with other requirements. For example, the light emitting layer 14c may be an electron transporting light emitting layer 14c or may be a hole transporting light emitting layer 14c. In addition, each of the layers 14a to 14e can be formed in a stack structure. For example, the light emitting layer 14c may be a white light emitting element which is further formed of a blue light emitting part, a green light emitting part and a red light emitting part.

In addition, the organic layer 14 is not limited to the foregoing layer structure so far as the electron injection layer 14e using a material having an azaaryl structure is provided while coming contact with the light emitting layer 14c, and a stack structure can be selected depending on the situation. For example, the light emitting layer 14c may be a hole transporting light emitting layer 14c. Also, in the foregoing respective organic layers, for example, the hole injection layer 14a and the hole transport layer 14b may be of a stack structure composed of plural layers, respectively.

Next, for the purpose of injecting an electron with good efficiency, the cathode 15 is configured by using a material having a small work function from a vacuum level of an electrode material, and for example, it is configured by an alkaline earth metal or an alloy thereof such as MgAg and Ca, an electrode of Al, etc., or LiF or the like.

In particular, here, since the display device 11 is of an upward lighting system, the cathode 15 is configured of a light transmitting material. In this case, the display device 11 may be configured to have a cavity structure in which emitting light is resonated between the anode 13 and the cathode 15 and extracted by making the cathode 15 semi-light transmitting and reflective.

Such a cathode 15 is configured to have a single-layered structure or a multilayered structure. For example, when the cathode 15 is configured to have a three-layered structure, a first layer of the cathode 15 configuring the side of the organic layer 14 is configured by using a material having a small work function and having good light transmissibility. Examples of such a material include LiF. A second layer is configured by using a material having good light transmissibility such as MgAg. A third layer may be provided with a transparent lanthanoid based oxide layer for suppressing the deterioration of the electrode. Thus, this third layer becomes a sealing electrode which is also able to extract the light emission.

The cathode 15 is not limited to the foregoing three-layered structure. The cathode 15 may be configured to have a single-layered structure or a two-layered structure so far as it is a stack structure necessary in dividing the function of each of the layers configuring the cathode 15. Furthermore, the cathode 15 may be configured to have a stack structure in which a transparent electrode such as ITO is sandwiched for an interlayer. Needless to say, the cathode 15 may take an optimum composition or stack structure for the device to be prepared.

In addition, in the cathode 15, the layer coming into contact with the electron injection layer 14e may be configured by a layer containing at least one of alkali metals, alkaline earth metals, lanthanoids (for example, La, Ce, Pr, Nd, Sm, Eu, Gd, Tb, Dy, Ho, Er, Tm, Yb, and Lu), and oxides, complex oxides and fluorides thereof.

The respective layers configuring the cathode 15 having the foregoing configuration is formed by a measure such as a vacuum vapor deposition method, a sputtering method, and a plasma CVD method. In the case where the driving system of the display unit configured by using this display device 11 is an active matrix system, the cathode 15 may be formed in a solid film form on the substrate 12 in a state that it is electrically insulated from the anode 13 by a non-illustrated dielectric film covering the surroundings of the anode 13 and the organic layer 14 and used as a common electrode to the respective pixels.

In the display device 11 of the embodiment which has been described previously, a material having an azaaryl structure with very good electron transport properties is used in the electron injection layer 14e, and this electron injection layer 14e is provided while coming into contact with the light emitting layer 14c without providing an electron transfer layer.

Thus, it has become possible to tremendously enhance the electron injection properties from the cathode 15 into the light emitting layer 14c and to largely lower a driving voltage. Also, since the electron injection properties into the light emitting layer 14c are tremendously enhanced, it becomes possible to bias a recoupling between a hole and an electron in the light emitting layer 14c towards the side of the anode 13 far from the cathode 15. Thus, extinction due to diffusion of an exciton into the metal of the cathode 15 does not occur. Moreover, since an electron transport layer is not present, energy transfer of the exciton in the light emitting layer 14c into the electron transport layer is not generated, and an energy loss of the exciton of the light emitting layer 14c becomes small, whereby the current efficiency can be improved.

In particular, as shown in the Examples as described later, by using the electron injection layer 14e whose thickness is made thinner, large effects for lowering the driving voltage and improving the current efficiency are obtained, and these effects become sure by adjusting the thickness of the electron injection layer 14e at not more than 10 nm.

In addition, in the display device 11 according to the embodiment of the invention, since the related-art electron transport layer with a low degree of charge transfer is not provided, a disturbance in charge balance is small, and the stability at the time of driving is kept, thereby achieving a long life. In other words, by providing the electron injection layer 14e while coming into contact with the light emitting layer 14c without providing an electron transport layer, there is not caused such a problem that the electron injection is suppressed by influences of the degree of charge transfer in the electron transport layer, whereby the carrier balance is liable to be lost. Thus, it has become possible to efficiently inject a necessary and sufficient electron into the light emitting layer 14c. Then, by making this electron injection layer 14e thin, it becomes possible to make an injection factor (injection balance between an electron and a hole in the light emitting layer 14c) y closed to 1 and to achieve a long life. In particular, as shown in the Examples as described later, by adjusting the thickness of the electron injection layer 14e at not more than 7 nm, such effects become sure.

In the light of the above, according to the configuration of the embodiment of the invention, it becomes possible to simultaneously achieve both an improvement of current efficiency and a long life which have hitherto been considered to be in a reciprocal relationship.

As a result, by using the display device according to the embodiment of the invention capable of devising to lower a driving voltage and to improve a current efficiency, it becomes possible to realize a display unit which is low in electric power consumption and excellent in long-term reliability.

In addition, as shown in the Examples as described later, according to the configuration of the embodiment of the invention, even when the light emitting layer 14c does not contain a basic skeleton capable of revealing electron transport properties such as an oxadiazole skeleton, a triazole skeleton, a phenanthrene skeleton, and a quinoline skeleton, the foregoing effects can be obtained. In other words, the configuration according to the embodiment of the invention is a configuration capable of devising to lower a driving voltage and to improve a current efficiency and devising to achieve a long life without being influenced by an organic material configuring the light emitting layer 14c. Accordingly, in the case where the organic material configuring the light emitting layer 14c is configured by using an organic material composed of only carbon and hydrogen, even when it contains a material generally used as a hole transport material and having a tertiary amine skeleton which is considered to become instable due to coupling with an electron, the same effects can be obtained.

Here, there have hitherto been a number of reports to describe that by positively injecting an electron into an organic material having the foregoing tertiary amine skeleton, oxidation and reduction properties of an organic molecule become instable and the deterioration becomes extremely fast [see, for example, Hany Aziz, et al., Science, Vol. 283, pages 1990 to 1992 (1999)]. However, according to the configuration of the embodiment of the invention, extremely effective effects which are contrary to such common knowledge in the related art are obtained.

Incidentally, the display device according to the embodiment of the invention is not limited to a display device which is used for a display unit of an active matrix system using a TFT substrate. The display device according to the embodiment of the invention can be applied to a display device which is used for a display unit of a passive system, and the same effect (an improvement of long-term reliability) can be obtained.

In the foregoing embodiment, the case of extracting the light emission from the side of the cathode 15 provided in an opposite side to the substrate 12 (upward lighting type) has been described. However, the embodiment according to the invention is also applicable to a display device of a “transmission type” in which the light emission is extracted from the side of the substrate 12 by configuring the substrate 12 by using a transparent material. In this case, in the stack structure as described previously by referring to FIG. 1, the anode 13 on the substrate 12, which is composed of a transparent material, is configured by using, for example, a transparent electrode material having a large work function such as ITO. Thus, the emitting light is extracted from both the side of the substrate 12 and the opposite side to the substrate 12. In such a configuration, by configuring the cathode 15 by using a reflecting material, the emitting light is extracted only from the side of the substrate 12. In this case, a sealing electrode made of, for example, AuGe, An, or Pt may be provided in the uppermost layer of the cathode 15.

In addition, even when the stack structure as described previously by referring to FIG. 1 is configured by inversely stacking the cathode 15 from the side of the substrate 12 made of a transparent material, thereby forming the anode 13 as an upper electrode, a display device of a “transmission type” in which the emitting light is extracted from the side of the substrate 12 can be configured. In this case, by changing the anode 13 as an upper electrode to a transparent electrode, the emitting light can also be extracted from both the side of the substrate 12 and the opposite side to the substrate 12.

The display device which has been described in the foregoing embodiment is also applicable to a display device of a stack type resulting from stacking units of an organic layer having a light emitting layer. The “stack type” as referred to herein means a multiphoton emission element (MPE element). For example, JP-A-11-329748 describes an element which is characterized by electrically welding plural organic light emitting elements in series via an intermediate conductive layer.

Furthermore, JP-A-2003-45676 and JP-A-2003-272860 disclose an element configuration for realizing a multiphoton emission element (MPE element) and describe detailed working examples. According to these patent documents, it is described that in the case where two units of an organic layer are stacked, the cd/A can be ideally increased two times without causing a change in the 1 m/W and that in the case where three units of an organic layer are stacked, the cd/A can be ideally increased three times without causing a change in the 1 m/W.

Accordingly, in the case where the embodiment of the invention is used in a stack type, realization of a long life due to the improvement in efficiency by the stack type and an effect for realizing a long life in the embodiment of the invention become a synergistic effect, whereby an element having an extremely long life can be obtained.

### EXAMPLES

Next, manufacturing procedures of display devices of concrete Examples according to the embodiment of the invention and Comparative Examples against these Examples will be described below along with evaluation results thereof.

### Examples 1 to 10

In each of Examples 1 to 10, in the foregoing embodiment, the display device 11 having the configuration as described previously by referring to FIG. 1 was formed. However, in each of these Examples, the respective material was used in each thickness as the electron injection layer 14e. First of all, the manufacturing procedures of the display device 11 of each of Examples 1 to 10 will be described below.

On the substrate 12 made of a glass plate of 30 mm×30 mm, an Ag alloy (thickness: about 100 nm) was formed by sputtering as the anode 13; and for the purpose of enhancing hole injection properties, ITO (thickness: about 10 nm) was formed thereon by sputtering. Next, an area other than a light emitting region of 2 mm×2 mm of the anode 13 was masked by an SiO₂ dielectric film (not illustrated) which had been formed by vapor deposition, thereby preparing a cell for organic electric field light emitting element.

Next, HI-406 (a trade name, manufactured by Idemitsu Kosan Co., Ltd.) was formed in a thickness of 10 nm (vapor deposition rate: 0.2 to 0.4 nm/sec) as the hole injection layer 14a by a vacuum vapor deposition method. Incidentally, the HI-406 is a hole injecting material.

Then, HT-320 (a trade name, manufactured by Idemitsu Kosan Co., Ltd.) was formed in a thickness of 10 nm (vapor deposition rate: 0.2 to 0.4 nm/sec) thereon as the hole transport layer 14b by a vacuum vapor deposition method. Incidentally, the HT-320 is a hole transporting material.

In addition, the following ADN [9,10-di-(2-naphthyl)-anthracene] as a host and BD-052x (a trade name, manufactured by Idemitsu Kosan Co., Ltd.) as a dopant were subjected to dual-source vapor deposition as the light emitting layer 14c in a dopant concentration such that a thickness ratio was 5% by a vacuum vapor deposition method. On that occasion, the thickness of the light emitting layer 14c was adjusted such that a total thickness together with the electron injection layer 14e to be next formed was 36 nm. Incidentally, the AND is a material composed of only carbon and hydrogen; and the BD-052x is an organic material having a tertiary amine skeleton.

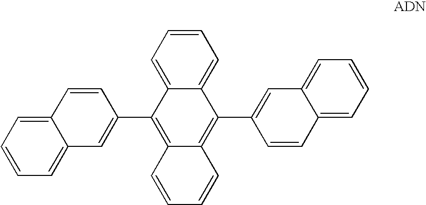

Next, by using each of materials as shown in the following Table 1, the electron injection layer 14e was formed in a thickness of from 2 to 10 nm (vapor deposition rate: 0.1 nm/sec) by a vacuum vapor deposition method.

TABLE 1

| | | | | | (1) | (2) | (3) | (4) |
|---|---|---|---|---|---|---|---|---|
| | Electron | | Electron injection layer | | Driving | Current | Life | Increase of |
| | transport | | | Thickness | voltage | efficiency | 10% down | driving voltage |
| | layer | | Material | (nm) | (V) | (cd/A) | (hr) | (ΔV) |
| Example 1 | Nil | | Formula (1) | 2 | 3.3 | 3.5 | 110 | 0.02 |
| Example 2 | | | | 4 | 3.3 | 3.4 | 110 | 0.02 |
| Example 3 | | | | 5 | 3.2 | 3.5 | 110 | 0.02 |
| Example 4 | | | | 7 | 3.3 | 3.5 | 105 | 0.03 |
| Example 5 | | | | 10 | 3.3 | 3.3 | 25 | 1.00 |
| Example 6 | | | Formula (2) | 5 | 3.5 | 3.5 | 160 | 0.02 |
| Example 7 | | | | 7 | 3.5 | 3.5 | 160 | 0.02 |
| Example 8 | | | | 10 | 3.0 | 2.5 | 40 | 0.90 |
| Example 9 | | | Formula (3) | 5 | 3.8 | 3.3 | 95 | 0.03 |
| Example 10 | | | Formula (4) | 3 | 3.4 | 3.3 | 100 | 0.05 |
| Comparative | Alq: | 20 nm | Nil | | 5.5 | 1.8 | 92 | 0.10 |
| Example 1 | | | | | | | | |
| Comparative | Nil | | Formula (1) | 20 | 6.0 | 2.3 | 9 | 1.10 |
| Example 2 | | | | | | | | |
| Comparative | Alq.: | 15 nm | Formula (1) | 5 | 6.3 | 1.8 | 31 | 0.30 |
| Example 3 | | | | | | | | |

The organic layer 14 of from the hole injection layer 14a to the electron injection layer 14e was formed in the foregoing manner. Thereafter, LiF was formed in a thickness of about 0.3 nm (vapor deposition rate: 0.01 nm/sec) as a first layer of the cathode 15 by a vacuum vapor deposition method; and MgAg was then formed in a thickness of 10 nm as a second layer of the cathode 15 by a vacuum vapor deposition method, thereby providing the cathode 15 having a two-layered structure.

### Comparative Example 1

In Comparative Example 1, a display device was prepared in the same manner as in Example 1, except for providing an electron transport layer made of an alumiquinolinol complex (Alq3: 8-hydroxyquinoline aluminum) in a thickness of 20 nm in place of the electron injection layer 14e.

### Comparative Example 2

In Comparative Example 2, a display device was prepared in the same manner as in Example 1, except for changing the thickness of the electron injection layer 14e to 20 nm.

### Comparative Example 3

In Comparative Example 3, a display device was prepared in the same manner as in Example 3, except for providing an electron transport layer made of an alumiquinolinol complex (Alq3) in a thickness of 15 nm between the light emitting layer 14c and the electron injection layer 14e.

Evaluation Results

In the case of driving each of the thus prepared display devices of Examples 1 to 10 and Comparative Examples 1 to 3 at a current density of 10 mA/cm², (1) a driving voltage (V) and (2) a current efficiency (cd/A) were measured and summarized in Table 1. By subjecting each of these display devices to constant-current driving at a current density of 125 mA/cm², (3) a time for reduction of a relative luminance by 10% was measured as a life with an initial luminance being defined as “1”; and on that occasion, (4) an increase width of driving voltage (ΔV) was measured, both of which were summarized in Table 1.

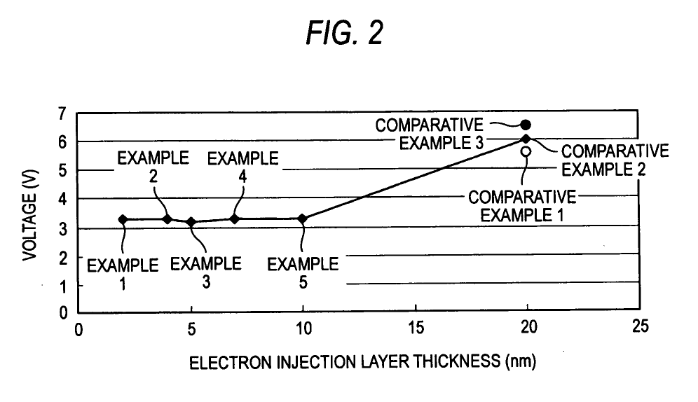

FIG. 2 shows a relationship between an electron injection layer thickness (nm) of each of the display devices of Examples 1 to 5 and (1) a driving voltage (V). This FIG. 2 also shows a relationship between a thickness (nm) of the total sum of the electron injection layer and the electron transport layer of each of the display devices of Comparative Examples 1 to 3 and (1) a driving voltage (V).

It is understood from the graph of FIG. 2 that in Examples 1 to 5 to which the configuration according to the embodiment of the invention is applied, the driving voltage (1) can be reduced to about ½ as compared with that in Comparative Examples 1 and 3. Thus, it was confirmed that by applying the configuration according to the embodiment of the invention, the driving voltage of the display device can be reduced. Furthermore, in Comparative Example 2 in which the thickness of the electron injection layer 14e is 20 nm, the driving voltage was large in the same level as in Comparative Examples 1 and 3. It was confirmed from this fact that by thinning the thickness of the electron injection layer 14e to a degree of less than 20 nm, and preferably not more than 10 nm, the effect for reducing the driving voltage becomes large. Incidentally, as shown in Table 1, in the display devices of Examples 6 to 10 to which the configuration according to the embodiment of the invention is applied, it was confirmed that the driving voltage can also be reduced to the same degree as in Examples 1 to 5.

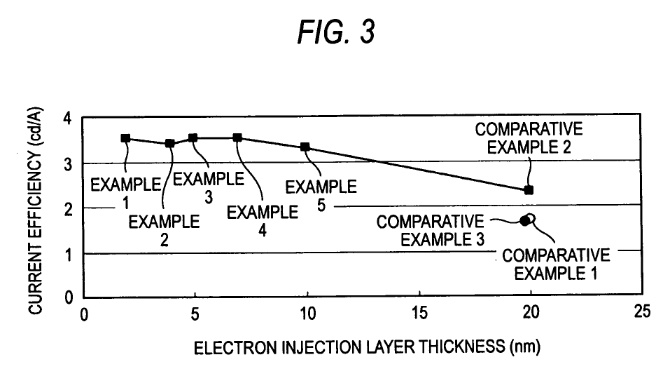

FIG. 3 is a graph to show a relationship between an electron injection layer thickness (nm) of each of the display devices of Examples 1 to 5 and (2) a current efficiency (cd/A). This FIG. 3 also shows a relationship between a thickness (nm) of the total sum of the electron injection layer and the electron transport layer of each of the display devices of Comparative Examples 1 to 3 and (2) a current efficiency (cd/A).

It is understood from the graph of FIG. 3 that in Examples 1 to 5 to which the configuration according to the embodiment of the invention is applied, the current efficiency (2) can be improved to a degree of about 1.5 times as compared with that in Comparative Examples 1 and 3. Thus, it was confirmed that by applying the configuration according to the embodiment of the invention, the current density of the display device can be improved. Furthermore, in Comparative Example 2 in which the thickness of the electron injection layer 14e is 20 nm, though the current efficiency was higher than that in Comparative Examples 1 and 3, it was lower than that in Examples 1 to 5. It was confirmed from this fact that by thinning the thickness of the electron injection layer 14e to a degree of less than 20 nm, and preferably not more than 10 nm, the effect for improving the current efficiency becomes large. Incidentally, as shown in Table 1, in the display devices of Examples 6 to 10 to which the configuration according to the embodiment of the invention is applied, it was confirmed that the current efficiency can also be improved to the same degree as in Examples 1 to 5.

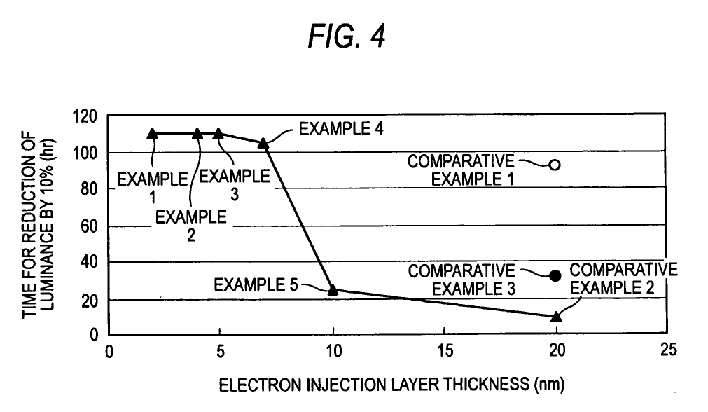

FIG. 4 is a graph to show a relationship between an electron injection layer thickness (nm) of each of the display devices of Examples 1 to 5 and (3) a life (hr). This FIG. 4 also shows a relationship between a thickness (nm) of the total sum of the electron injection layer and the electron transport layer of each of the display devices of Comparative Examples 1 to 3 and (3) a life (hr).

It is understood from the graph of FIG. 4 that among the Examples to which the configuration according to the embodiment of the invention is applied, Examples 1 to 4 in which the thickness of the electron injection layer is not more than 7 nm achieve a long life exceeding that in Comparative Examples 1 to 3 and are able to make a life of about 20% longer than that in Comparative Example 1 in which the life is the longest among the Comparative Examples. It was confirmed from this fact that by adjusting the thickness of the electron injection layer at not more than 7 nm, the effect for making the life long is especially large. Incidentally, as shown in Table 1, in the display devices of Examples 6 to 10 to which the configuration according to the embodiment of the invention is applied, it was confirmed that by adjusting the thickness of the electron injection layer at not more than 7 nm, the effect for making the life long is especially large similar to Examples 1 to 5.

Incidentally, in the case where the thickness of the electron injection layer 14e is 10 nm, though the effect for making the life long is not obtained, the effect for realizing a low voltage and a high efficiency is obtained. For that reason, it is possible to effectively use a display device which is configured to have a thickness of the electron injection layer 14e of 10 nm.

### Examples 11 to 14

In each of Examples 11 to 14, the foregoing display device 11 was also formed. These Examples are characterized by containing a substance capable of emitting phosphorescence in the light emitting layer 14c. Furthermore, the display device 11 has a cavity structure in which emitting light is resonated between the anode 13 and the cathode 15. While concrete configurations will be hereunder described, the configurations other than the organic layer are the same as in Examples 1 to 10, and therefore, explanations thereof are omitted.

After forming the anode 13 on the substrate 12, CuPc (copper phthalocyanine) was formed in a thickness of 10 nm (vapor deposition rate: 0.2 to 0.4 nm/sec) as the hole injection layer 14a by a vacuum vapor deposition method. Incidentally, the CuPc is a hole injecting material.

Next, α-NPD [N,N′-bis(1-naphthyl)-N,N′-diphenyl-1,1′-biphenyl-4,4′-diamine] was formed in a thickness of 18 nm (vapor deposition rate: 0.2 to 0.4 nm/sec) as the hole transport layer 14b. Incidentally, the α-NPD is a hole transporting material.

Next, CBP (4,4′-N,N′-dicarbazole-biphenyl) as a host and Ir(ppy)₃ (iridium-phenylpyridine complex) as a dopant were subjected to dual-source vapor deposition as the light emitting layer 14c in a dopant such that a thickness ratio was 5% by a vacuum vapor deposition method. On that occasion, the film formation was carried out such that the thickness of the light emitting layer was 25 nm.

Next, an adjustment layer was formed as a part of the light emitting layer 14c. The adjustment layer was made of a blue light emitting layer and formed by dual-source vapor deposition by using AND as a host and BD-052x (a trade name, manufactured by Idemitsu Kosan Co., Ltd.) as a dopant in a dopant concentration such that a thickness ratio was 5% by a vacuum vapor deposition method. The adjustment layer is formed for the purpose of adjusting an optical path of the cavity structure. The thickness of the adjustment layer was adjusted such that a total thickness of the light emitting layer 14c and the electron injection layer 14e (as described later) was 35 nm.

Next, the electron injection layer 14e was formed in a thickness of 4, 7, 15 and 25 nm (vapor deposition rate: 0.1 nm/sec), respectively by using the material represented by the formula (1) by a vacuum vapor deposition method.

After thus forming the organic layer 14, the cathode 15 was formed.

### Comparative Example 4

In Comparative Example 4 as a comparative example against Examples 11 to 14, BCP (2,9-dimethyl-4,7-diphenyl-1,10-phenanthroline) was subjected to film formation as a hole block layer instead of using the electron injection layer 14e, and an alumiquinolinol complex (Alq3) was subjected to film formation thereon as an electron transport layer.

Evaluation Results

With respect to each of the thus prepared display devices of Examples 11 to 14 and Comparative Example 4, (1) a driving voltage (V) and (2) a current efficiency (cd/A) were measured at a current density of 10 mA/cm². Also, by subjecting each of these display devices to constant-current driving at 1.5 mA, (3) a time for reduction of a relative luminance to 0.9 was measured as a life with an initial luminance being defined as “1”; and on that occasion, (4) an increase width of driving voltage (ΔV) was measured, both of which were summarized in Table 2.

TABLE 2

| | | | | (1) | (2) | (3) | (4) |
|---|---|---|---|---|---|---|---|
| | Hole block | Electron injection layer | | Driving | Current | Life | Increase of |
| | layer/Electron | | Thickness | voltage | efficiency | 10% down | driving voltage |
| | transport layer | Material | (nm) | (V) | (cd/A) | (hr) | (ΔV) |
| Example 11 | Nil | Formula (1) | 4 | 4.4 | 52.9 | 36 | 0.02 |
| Example 12 | | | 7 | 4.6 | 52.0 | 34 | 0.02 |
| Example 13 | | | 15 | 6.5 | 48.0 | 25 | 0.02 |
| Example 14 | | | 25 | 8.0 | 39.0 | 23 | 0.03 |

| | | | | | | |
|---|---|---|---|---|---|---|
| Comparative | BCP/Alq | Nil | 6.6 | 42.8 | 38 | 0.10 |
| Example 4 | | | | | | |

It is understood from Table 2 that in Examples 11 and 12 in which the thickness of the electron injection layer 14e is 4 nm and 7 nm, respectively, the driving voltage (1) was suppressed, and the current density (2) was good as compared with Comparative Example 4. In general, it is known that a display device using a material capable of emitting phosphorescence requires a hole block layer and becomes high in voltage. However, it was understood from the results as shown in Table 2 that a display device using a material capable of emitting phosphorescence can be configured without using a hole block layer and can be driven at a low voltage.

Incidentally, while the explanation has been omitted in the foregoing Examples, in the case of using a material represented by the formula (2) or (4) for the electron injection layer 14e, the same results were also obtained.

### Examples 15 to 24

In each of Examples 15 to 24, the foregoing display device 11 was also formed. While concrete configurations will be hereunder described, the configurations other than the anode 13 and the organic layer 14 are the same as in Examples 1 to 10, and therefore, explanations thereof are omitted.

On the substrate 12 made of a glass plate of 30 mm×30 mm, an Al alloy (thickness: about 100 nm) was formed by sputtering as the anode 13. Next, a cell for organic electric field light emitting element masked by an SiO₂ dielectric film which had been formed by vapor deposition was prepared.

Next, as a hole injection layer 14a, HI-406 (a trade name, manufactured by Idemitsu Kosan Co., Ltd.) as a host and an electron accepting material represented by each of the following formulae (28) to (29) as a dopant were subjected to dual-source vapor deposition by a vacuum vapor deposition method such that a dopant concentration was a concentration as shown in Table 3 in terms of a thickness ratio. On that occasion, the thickness of the hole injection layer 14a was adjusted at 10 nm.

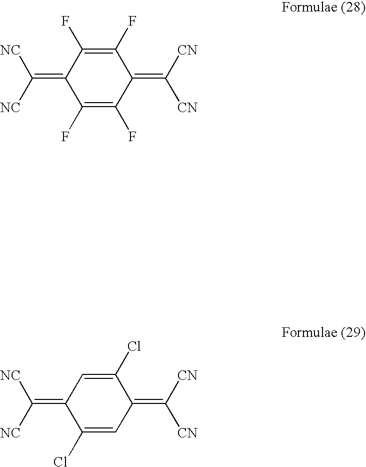

Then, HT-320 (a trade name, manufactured by Idemitsu Kosan Co., Ltd.) was formed in a thickness of 10 nm (vapor deposition rate: 0.2 to 0.4 nm/sec) thereon as the hole transport layer 14b by a vacuum vapor deposition method.

In addition, by using ADN as a host and BD-052x (a trade name, manufactured by Idemitsu Kosan Co., Ltd.) as a dopant, the light emitting layer 14c was prepared by film formation of these materials in a dopant concentration of 5% in terms of a thickness ratio in a thickness of 31 nm by a vacuum vapor deposition method.

Next, the electron injection layer 14e was formed in a thickness of 5 nm (vapor deposition rate: 0.1 nm/sec) by using the material represented by the formula (1) by a vacuum vapor deposition method.

After thus forming the organic layer 14, the cathode 15 was formed.

### Comparative Example 5

In Comparative Example 5, the same procedures as in Examples 15 to 24 were followed, except for using HI-406 singly as the hole injection layer 14a.

### Comparative Example 6

In Comparative Example 6, a film made of an Ag alloy (thickness: about 100 nm) was formed as the anode 13 by sputtering, and a film made of ITO (thickness: about 10 nm) was further formed thereon by sputtering. Furthermore, HI-406 was used singly as the hole injection layer 14a. Besides, the same procedures as in Examples 15 to 24 were followed.

Evaluation Results

With respect to each of the thus prepared display devices of Examples 15 to 24 and Comparative Examples 5 and 6, (1) a driving voltage (V) and (2) a current efficiency (cd/A) were measured at a current density of 10 mA/cm². Also, by subjecting each of these display devices to constant-current driving at 1.5 mA, (3) a time for reduction of a relative luminance to 0.9 was measured as a life with an initial luminance being defined as “1”; and on that occasion, (4) an increase width of driving voltage (ΔV) was measured, both of which were summarized in Table 3.

TABLE 3

| | | | | | (1) | (2) | (3) | (4) |
|---|---|---|---|---|---|---|---|---|
| | | Hole injection layer | | | Driving | Current | Life | Increase of |
| | | | | Dopant | voltage | efficiency | 10% down | driving voltage |
| | Anode | Host | Dopant | concentration | (V) | (cd/A) | (hr) | (ΔV) |
| Example 15 | Al alloy | HI-406 | Formula (28) | 5% | 7.2 | 3.5 | 100 | 0.12 |
| Example 16 | | | | 10% | 5.1 | 3.4 | 95 | 0.07 |
| Example 17 | | | | 20% | 4.7 | 3.6 | 100 | 0.07 |
| Example 18 | | | | 30% | 4.2 | 3.4 | 100 | 0.03 |
| Example 19 | | | | 50% | 3.9 | 3.3 | 105 | 0.02 |
| Example 20 | | | | 70% | 3.7 | 3.2 | 100 | 0.02 |
| Example 21 | | — | | 100% | 3.5 | 3.1 | 110 | 0.02 |
| Example 22 | | HI-406 | Formula (29) | 30% | 4.1 | 3.4 | 95 | 0.10 |
| Example 23 | | | | 50% | 3.8 | 3.3 | 110 | 0.03 |
| Example 24 | | | | 70% | 3.4 | 3.3 | 105 | 0.01 |
| Comparative | | HI-406 | | | 16.0 | 0.2 | 10 | 1.20 |
| Example 5 | | | | | | | | |
| Comparative | Ag/ITO | | | | 3.2 | 3.5 | 110 | 0.02 |
| Example 6 | | | | | | | | |

I was understood from Table 3 that in the case of using an Al alloy as the anode 13, when HI-406 is used singly as the hole injection layer 14a (Comparative Example 5), the driving voltage (1) is high, and the current efficiency (2) is low, whereas in Examples 15 to 24 in which a mixture of HI-406 (host) and the electron accepting material represented by the formula (28) or (29) (dopant) is used as the hole injection layer 14a, the driving voltage (1) is suppressed as compared with Comparative Example 5, and the current efficiency (2) is improved. Furthermore, it was understood that when the electron accepting material (dopant) is mixed in a high concentration in the hole injection layer 14a, the same characteristics as in the case of using Ag/ITO as the anode 13 (Comparative Example 6) are obtained.

It should be understood by those skilled in the art that various modifications, combinations, sub-combinations and alternations may occur depending on design requirements and other factors insofar as they are within the scope of the appended claims or the equivalents thereof.

What is claimed is:

1. A display device comprising:
an anode,
a cathode, and
an organic layer provided with at least a light emitting layer interposed between the anode and the cathode,
wherein the organic layer is provided with an electron injection layer which is provided in a state that it comes into contact with the light emitting layer between the cathode and the light emitting layer, and
the electron injection layer includes a material having an azaaryl structure.

2. The display device according to claim 1, wherein
the electron injection layer has a thickness of not more than 10 nm.

3. The display device according to claim 1, wherein
the electron injection layer has a thickness of not more than 7 nm.

4. The display device according to claim 1, wherein
the light emitting layer consists essentially of carbon and hydrogen.

5. The display device according to claim 1, wherein
the light emitting layer comprises a tertiary amine.

6. The display device according to claim 1, wherein
the light emitting layer contains a substance capable of emitting phosphorescence.

7. The display device according to claim 1, wherein
the organic layer is provided with a hole injection layer, and the hole injection layer comprises at least two different organic materials.

8. The display device according to claim 1, wherein
the electron injection layer contains at least one of alkali metals, alkaline earth metals, lanthanoids including La, Ce, Pr, Nd, Sm, Eu, Gd, Tb, Dy, Ho, Er, Tm, Yb and Lu, and oxides, complex oxides and fluorides thereof.
